(19) United States
(12) Patent Application Publication
(10) Pub. No.: US 2002/0195902 A1
(43) Pub. Date: Dec. 26, 2002

(54) Cell driving type actuator and method for manufacturing the same

(75) Inventors: Yukihisa Takeuchi, Nishikamo-Gun (JP); Nobuo Takahashi, Owariasahi-City (JP)

Correspondence Address: BURR & BROWN, PO BOX 7068, SYRACUSE, NY, 13261-7068, US

(73) Assignee: NGK Insulators, Ltd., Nagoya-City (JP)

(21) Appl. No.: 09/888,048

(22) Filed: Jun. 22, 2001

(30) Foreign Application Priority Data
Jun. 22, 2001 (JP) 2001-189718

(51) Int. Cl. H01L 41/08

(52) U.S. Cl. 310/328

(57) ABSTRACT

A piezoelectric/electrostrictive actuator wherein a plurality of piezoelectric/electrostrictive elements are arranged like teeth of a comb in alignment on a base plate, said actuator being driven by the displacement of said piezoelectric/electrostrictive elements. A cell formed by closed a plane facing said base plate and being positioned between two adjacent piezoelectric/electrostrictive elements with a cover plate is formed in such a manner that it is independent of its adjacent cells. Activation with a higher field strength is possible, and a greater displacement can be realized with a weaker field strength.

### BACKGROUND OF THE INVENTION AND RELATED ART

The present invention relates to a cell driving type piezoelectric/electrostrictive actuator. More particularly, it relates to a cell driving type actuator having cells each being formed independently by two piezoelectric/electrostrictive elements, wherein the piezoelectric/electrostrictive elements forming the cell are displaced by a driving electric field applied in the same direction as the polarization field of the piezoelectric/electrostrictive elements.

There is known, as a conventional piezoelectric/electrostrictive actuator, for instance, a piezoelectric/electrostrictive actuator being driven in the shear mode and being used in an ink jet head. This is a piezoelectric/electrostrictive actuator 71 having such a structure shown in FIG. 7; said piezoelectric/electrostrictive elements which is comb teeth 76 and driving parts 74 as well being formed like teeth of a comb on a base plate 72, and slits 75 between the comb teeth 76 being closed by a cover plate 77 so as to form cells 73 in a substantially rectangular form. An ink head 70 wherein the cell 73 is used as an ink chamber is constituted by closing the respective openings at the front end of comb teeth in the piezoelectric/electrostrictive actuator 71 with a nozzle plate 9 having nozzles 8; the comb teeth 76 is deformed so as to change the volume of the cell 73 by applying a driving electric field in the direction perpendicular to the direction of the polarization field in comb teeth 76 as the driving parts 74 made of piezoelectric/electrostrictive material, thereby the ink filled in the cell 73 can be ejected.

Furthermore, the driving method for forming the displacement by means of the driving electric field in the direction perpendicular to the polarization field of the piezoelectric/electrostrictive elements is called as the shear mode method.

Such a piezoelectric/electrostrictive actuator 71 has been constructed by the procedure shown in FIG. 8(a) FIG. 8(e):

Firstly, a piezoelectric/electrostrictive material 86 is provided as in FIG. 8(a), and fired, as shown in FIG. 8(b). Subsequently, the polarizing treatment is carried out, as shown in FIG. 8(c). In FIG. 8(d), the process of forming fine slits is carried out by using a dicing saw or the like, and the driving parts 74 causing the dislocation due to the driving electric field are formed like teeth of a comb in alignment by interposing the slits 75 to be a space for storing the ink therebetween. Electrodes 88 are formed on the walls of the slits 75, as shown in FIG. 8(e). Thereafter, as shown in FIG. 7, the cells 73 to be filled with an ink are formed by applying the cover plate 77 formed by a glass plate or the like thereto, and by closing the front ends of the comb teeth 76 with a nozzle plate 9 having nozzles 8.

Such a manufacturing method has, however, the following problems due to the machining of hard piezoelectric/electrostrictive materials:

The first problem is that it is time-consuming to machine the slits for constituting the cells, so that the method is unsuitable for mass production.

The second problem is that a satisfactory cleaning requires the complicated process since the mechanical strength is reduced after the slits are formed while a sufficient cleaning is needed after machining the slits since the resultant is polluted with either free abrasive grains for machining or a liquid for machining. Moreover, it requires inevitably a drying process. Additionally, the cost increases since facilities and the management for cleaning water and exhaust water are required.

The third problem is that it is difficult to form cells having a high aspect ratio of more than 10. This is because the slits for constituting the cells to be filled with an ink can not be machined with a width of approximately 60 μm or less due to the restriction derived from the thickness of the dicing blade used for the machining. Regarding the thickness of a comb tooth, i.e., a driving part, a limited value is automatically determined with respect to the depth, since the grinding strength is required for the dicing blade. As a result, it is difficult to form a high power actuator having a high density and a high strength.

Generally, the aspect ratio is defined by the ratio of the diameter and the axial length in the case of a cylindrical aperture, whereas, in the case of non-cylindrical aperture, for instance, the slit 75 providing a cell made by closing it in subsequent processing, as shown in FIG. 8(d), the aspect ratio is defined by the ratio of the minimum spacing between two facing comb teeth 76, i.e., the width of the slit 75, and the depth of the slit 75. A cell of a high aspect ratio means a cell having a slit whose depth is larger relative to the width.

The fourth problem is that the process of bonding parts is always required in the subsequent processing when one produces cells having a complicated form. This is because only straight and flat slits can be formed due to the machining with a dicing blade. Moreover, the deformation due to the piezoelectric stress extends up to the bounded end of the nozzle plate during operation as a consequence of the straight line machining, and thus it is liable to result in the reduction in the durability of the bonding surface.

The fifth problem is that the characteristics of the cells are liable to be deteriorated. This is because side surfaces of comb-like driving parts 74 are apt to become uneven since the slits are formed by the grinding process after firing. FIG. 9(a) and FIG. 9(b) are drawings for explaining this fact. FIG. 9(a) is a side view of the end surface viewed from Q in FIG. 8(d), and FIG. 9(b) shows an enlarged section of part N in FIG. 9(a). In the grinding process with the dicing saw, micro cracks and particles fractured inside the grains are often present in the side surfaces of comb-like driving parts 74 (comb teeth 76) due to the machining. As a result, the intrinsic performance of the material will not be attained or the device itself will break due to the propagation of micro cracks when the cells are driven.

Moreover, in the conventional piezoelectric/electrostrictive actuator 71, there are several problems attributed to the operation in the shear mode.

The sixth problem subsequent to the fifth problem, is that, after firing and carrying out the polarization treatment, the manufacturing process including heating at a temperature higher than the Curie temperature cannot be carried out, because the polarization in the piezoelectric/electrostrictive material disappears. In the case of fixing or wiring the actuator to, e.g., a circuit board, neither soldering by a reflow soldering method or the like nor bonding while heating can be carried out, otherwise, such a process suffers a thermal restriction and thus throughput is reduced, thereby increasing the cost of manufacturing. Moreover, a machining process inducing heat, such as laser processing or the like, also provides such a restriction.

Furthermore, as the seventh problem, it can be pointed out that the actuator cannot be driven with a high field strength which provides a change in the state of polarization, since the driving electric field is applied in the direction perpendicular to that of the polarization field. The high driving field strength gradually changes the state of polarization during the period of operation, hence reducing the magnitude of the strain. As a result, the basic performance of the actuator is reduced.

Moreover, in the conventional piezoelectric/electrostrictive actuator 71, there is a problem due to the structure in which the base plate, driving parts, and the cover plate are integrated in one body, inclusive of the problems resulting from the above-mentioned method for machining and the problem inherent in the shear-mode operation.

The eighth problem is that one may not make adjacent cells behave in the same way. FIG. 15 shows sectional views of an embodiment of piezoelectric/electrostrictive actuator 71 in deactivated and activated states. In the case that the driving electric field is in OFF state, the driving parts 74, i.e., the piezoelectric/electrostrictive elements are not deformed, whereas in the case that the driving electric field is ON state to the specified driving parts, the driving parts 74 are deformed. As can be appreciated from FIG. 15, an increase in the volume of a cell results in a decrease in the volume of its adjacent cell, since the driving part 74 acts as a driving component for the two cells 73. When, for instance, the piezoelectric/electrostrictive actuator 71 is used as the ink jet head 70 as shown in FIG. 7, the ink cannot be ejected simultaneously from adjacent cells. Therefore, at least twice operations are needed in order to spray ink particles to an article to be sprayed in the minimum spacing the sprayed inks. This is not preferable from the viewpoints of the improvement in the ink discharging rate.

The present invention has been completed in view of the above mentioned problems. That is, the theme to be solved by the invention is to provide a piezoelectric/electrostrictive actuator to which a high-temperature heating process can be applied, which ensures mass production at a low cost, which can be driven with a high-strength electric field, in which slit portions have cells of other than a straight line shape with cell width of 60 μm or less, and in which the cells have a high aspect ratio, thereby enabling a greater displacement to be realized with a weaker electric field, and also to provide a method for manufacturing such an actuator.

After making many investigations regarding the piezoelectric/electrostrictive actuator and the method for manufacturing the same, it is found that the above-mentioned theme can be dissolved by the piezoelectric/electrostrictive actuator and by the method for manufacturing it as shown below.

### SUMMARY OF THE INVENTION

That is, there is provided a cell driving type actuator wherein a plurality of piezoelectric/electrostrictive elements are arranged in alignment like teeth of a comb on a base plate and said actuator is a piezoelectric/electrostrictive actuator being driven by means of dislocation of piezoelectric/electrostrictive elements,

characterized in that each of cells is formed independently from its adjacent cells by closing respective planes being positioned between two adjacent piezoelectric/electrostrictive elements and facing the base plate with respective cover plates. In the present invention, it is preferable that the polarization field of the piezoelectric/electrostrictive elements is aligned in the same direction as the driving electric field.

In the cell driving type actuator according to the present invention, it is preferable that the degree of profile for the surface of a cell is approximately 8 μm or less, and it is also preferable that the ratio of the minimum spacing between the adjacent piezoelectric/electrostrictive elements for forming a cell to the minimum spacing between the base plate and the cover plate is approximately 1:2 to 1:40. It is further preferable that the ratio of the spacing between a cell and the adjacent cell to the minimum spacing between the base plate and the cover plate is approximately 1:2 to 1:40, and also that the minimum spacing between the adjacent piezoelectric/electrostrictive elements for forming a cell is approximately 60 μm or less. Moreover, it is preferable that the spacing between a cell and its adjacent cell is approximately 50 μm or less.

In the cell driving type actuator according to the invention, moreover, it is preferable that the surface roughness Rt of the wall surfaces of piezoelectric/electrostrictive elements where the elements face one another and form a cell is approximately 10 μm or less. It is preferable that the width of the comb-like piezoelectric/electrostrictive elements varies from the recess to the front end of the comb teeth, and it is also preferable that the spacings between the adjacent piezoelectric/electrostrictive elements for forming a cell, or, the spacings between the cell and its adjacent cell, may have at least two different distances.

In accordance with the present invention, moreover, a liquid discharging device equipped with the above-mentioned cell driving type actuator can be provided, wherein each cell is used as a liquid pressurizing chamber, and the piezoelectric/electrostrictive elements are displaced by applying a driving electric field thereto in the same direction as the polarization field of the piezoelectric/electrostrictive elements, and thus the liquid chamber is deformed, thereby enabling a liquid filled in the liquid chambers to be ejected in the direction of the front end of the comb teeth.

In the present invention, the two methods for manufacturing the cell driving type actuator are provided as shown below:

The first manufacturing method is directed to a method for manufacturing, by utilizing a punch and a die, a cell driving type actuator wherein a plurality of piezoelectric/electrostrictive elements are arranged in alignment like teeth of a comb on a base plate; each cell being formed by closing two adjacent piezoelectric/electrostrictive elements disposed on the base plate with a cover plate positioned at a plane facing the base plate in such a manner that said cell is formed independently from its adjacent cells,

characterized in that said method comprises the steps of:

providing a plurality of green sheets made of piezoelectric/electrostrictive material,

machining slit apertures in all the green sheets with the punch, and

laminating all the green sheets after positioning them so as to form a plurality of comb-like piezoelectric/electrostrictive layers.

The second manufacturing method is directed to a method for manufacturing, by utilizing a punch and a die, a cell driving type actuator wherein a plurality of piezoelectric/electrostrictive elements are arranged in alignment like teeth of a comb on a base plate; each cell being formed by closing two adjacent piezoelectric/electrostrictive elements disposed on the base plate with a cover plate positioned at a plane facing the base plate in such a manner that said cell is formed independently from its adjacent cells,

characterized in that said method comprises:

a step of providing a plurality of green sheets made of piezoelectric/electrostrictive material,

a first step of machining first slit apertures in a first green sheet with the punch,

a second step of moving the first green sheet upwards into tight contact with a stripper in the state of not withdrawing the punch from the first slit apertures,

a third step of moving the punch upwards in such a way that the front end of the punch is withdrawn slightly from the lowest part of the first green sheet which moves upwards,

a fourth step of machining second slit apertures in a second green sheet with the punch,

a fifth step of moving the second green sheet upwards, together with the first green sheet in the state of not withdrawing the punch from the second slit apertures,

and a sixth step of moving the punch upwards in such a way that the front end of the punch is withdrawn slightly from the lowest part of the second green sheet which moves upwards, and thereafter,

laminating a plurality of green sheets by repeating the fourth to sixth steps so as to form a plurality of comb-like piezoelectric/electrostrictive layers.

### BRIEF DESCRIPTION OF THE DRAWINGS

FIG. 1 is a perspective view of an embodiment of a cell driving type actuator according to the invention.

FIGS. 2(a)-(e) are schematic drawings for explaining an embodiment of a method for manufacturing a cell driving type actuator according to the invention.

FIGS. 3(a)-(e) are schematic drawings for explaining another embodiment of a method for manufacturing another cell driving type actuator according to the invention.

FIGS. 4(a)-(e) are schematic drawings for explaining another embodiment of a method for manufacturing another cell driving type actuator according to the invention.

FIGS. 5(a) and (b) are a side view of the cell driving type actuator according to the invention shown in FIGS. 2(a)-(e), viewed from the position P in FIG. 2(d) and an enlarged schematic sectional view of part M in FIG. 5(a), respectively.

FIGS. 6(a)-(e) are drawings for explaining an embodiment of a method for machining slit apertures in green sheets shown in FIGS. 2(a)-(e) and simultaneously laminating the green sheets wherein

FIG. 6(a) shows a first step for preparing the first sheet by mounting the initial green sheet onto a die;

FIG. 6(b) shows a step for punching the initial green sheet;

FIG. 6(c) shows a second step for preparing the second sheet by mounting the second green sheet;

FIG. 6(d) shows a step for punching the second green sheet; and

FIG. 6(e) is a drawing showing a step for punching all the sheets and for removing the laminated green sheets with a stripper after the lamination.

FIG. 7 is a perspective view of an embodiment of an ink jet head equipped with a conventional piezoelectric/electrostrictive actuator.

FIGS. 8(a)-(e) are schematic drawings showing an embodiment of a method for manufacturing a conventional piezoelectric/electrostrictive actuator.

FIGS. 9(a) and (b) are a side view of the conventional piezoelectric/electrostrictive actuator shown in FIGS. 8(a)-(e), viewed from position Q in FIG. 8(d), and an enlarged schematic sectional view of part N in FIG. 9(a), respectively.

FIGS. 10(a) and (b) are sectional views of the cell driving type actuator according to the invention, which is applied to a micro-mirror device as an example.

FIG. 11 is a sectional view of an embodiment of a liquid discharging device to which the cell driving type actuator according to the invention is applied, wherein the cells are not identical with each other regarding the cell width and cell spacing, and have at least two different dimensions.

FIG. 12 is a perspective view of an embodiment of a liquid-discharging device to which the cell driving type actuator according to the invention is applied, wherein the width of slits varies towards the front end of the comb teeth.

FIGS. 13(a) and (b) are sectional view of a transportation apparatuses to which the cell driving type actuator according to the invention is applied, wherein FIG. 13(a) shows an example where the slit width is kept at a fixed value, whereas FIG. 13(b) shows an example where the slit width varies.

FIG. 14 is sectional views showing the deactivated and activated states of the cell driving type actuator according to the invention.

FIG. 15 is sectional views showing the deactivated and activated states of the conventional cell driving type actuator.

### DESCRIPTION OF THE PREFERRED EMBODIMENTS

Referring now to the drawings, the cell driving type actuator according to the invention and the method for manufacturing the actuator will be concretely explained. However, the present invention is not restricted to such an explanation, rather various revisions, modifications and/or corrections are possible on the basis of the knowledge of a person skilled in the art, unless they are outside the scope of the invention.

In the present specification, the expression to drive an actuator means to drive at least one cell, and to drive a cell means to form a pressurized or a depressurized state in the cell by changing the volume of the cell with deforming the driving parts constituting the cell under application of a driving electric field.

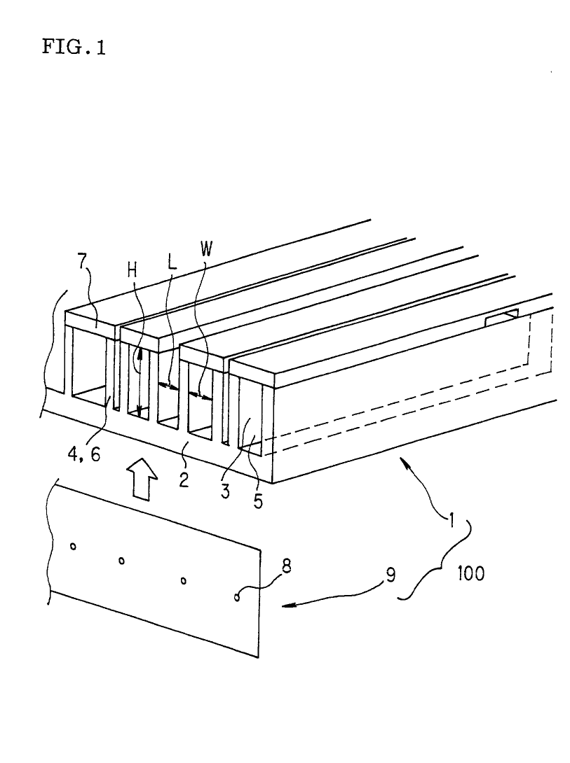

FIG. 1 is a perspective view of an embodiment of a cell driving type actuator according to the invention. In a cell driving type actuator 1, a plurality of piezoelectric/electrostrictive elements, which are regarded as comb teeth 6 or driving parts 4, are formed like teeth of a comb on a base plate 2, and approximately rectangle-shaped cells 3 are formed by closing the slits 5 with cover plates 7 at an area between two adjacent comb teeth 6.

For instance, a liquid discharging device 100 can be constituted by closing openings at the front end of the comb teeth of the cell driving type actuator with a nozzle plate 9 having nozzles 8, wherein the cells 3 are used as liquid chambers. A liquid in the cells 4 is ejected by changing the volume of the cells 4 with deformation in the comb teeth 6 by applying driving electric field to the comb teeth 6, i.e., the driving parts 4 made of piezoelectric/electrostrictive material, in the same direction as the polarization field. The liquid discharging device 100 can be applied, for instance, in the head of an ink jet printer, or in manufacturing DNA chips necessary for mixing liquids in a trace amount and for giving rise to a reaction therein, as well as for analyzing gene structure in the field of biotechnology; or in a micro droplet discharging apparatus which is used in coating processes in semiconductor device production.

The cell driving type actuator 1 according to the present invention is characterized in that the cells 3 formed by closing the surface facing the base plate 2 by the cover plates 7 at an area between two adjacent comb teeth 6 are constituted independently from its adjacent cells 3: not like the conventional piezoelectric/electrostrictive actuator, in which the base plate, comb teeth and cover plate are unified in one body so as to form a plurality of cells by a common cover plate, or in which one tooth, i.e., a driving part is served, as a driving member for the two cells. Furthermore, the cell driving type actuator 1 according to the present invention has a characterized point in that the polarization field of the piezoelectric/electrostrictive elements forming the driving part 4 is aligned in the same direction as the driving electric field.

Each of cells 3 has a structure in which it is closed by separate cover plates 7 and formed to be independently from its adjacent cells 3, thereby enabling each cell 3 to be driven completely independently of the other cells 3. Moreover, it is possible to operate the adjacent cells 3 each other in the same manner.

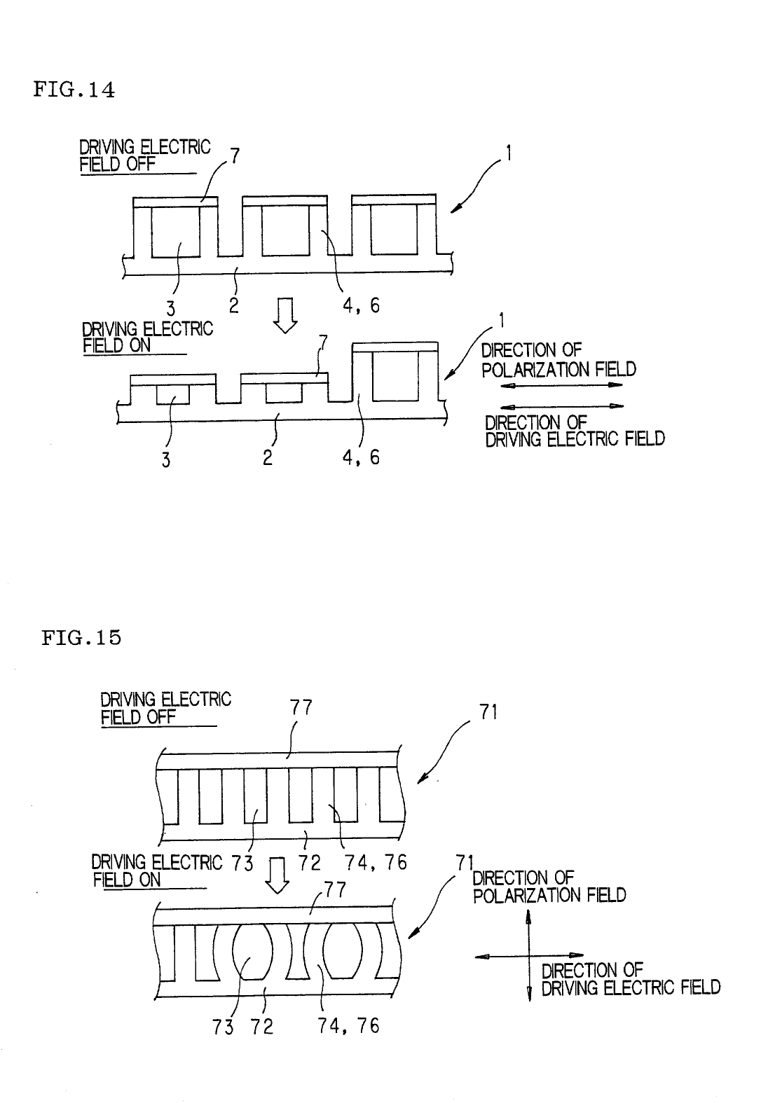

FIG. 14 shows example sectional views of the cell driving type actuator 1 according to the present invention in deactivated and activated states. When a driving electric field is in OFF state, the driving part 4, i.e., the piezoelectric/electrostrictive element does not deform, whereas, when the driving electric field is in ON state to a specified driving part4, the driving part 4 deforms. In this case, the cell 3 is constructed by two driving parts 4 arranged on the base plate 2 and by the cover plate 7, which closes only a plane between the two driving parts 4, said plane facing the base plate 2. Accordingly, the activation of the cell 3 and the activation of the adjacent cells 3 can be carried out independently of each other, without any restriction in the amount of displacement, and it is therefore possible to give rise to the same action for the two adjacent cells 3, as shown in FIG. 14. As a result, a reduced field strength is required to obtain the same magnitude of displacement compared with the conventional actuator.

On an occasion that the cell driving type actuator 1 is, for instance, used as the above-mentioned liquid discharging device 100, a liquid can be discharged simultaneously from the adjacent cells 3, hence the frequency of activating cells 3 is reduced compared with the conventional cells, thus succeeding in increasing the rate of liquid discharge. In a more concrete explanation, the cost of production can be greatly reduced compared with the conventional actuator, if the liquid-discharging device 100 is used in the production of DNA chips.

Since, moreover, the polarization field of the piezoelectric/electrostrictive elements comprising the driving parts is aligned in the same direction as the driving electric field, it is unnecessary to produce temporary or dummy electrodes for polarization and to apply the electric field thereto in the manufacturing process, thereby enhancing the throughput. In addition, it is possible to employ a manufacturing process of heating at a temperature higher than the Curie temperature, irrespective of the presence of the polarization treatment. As a result, it is possible to fix and bond the actuator to, e.g., a circuit board with reflow-soldering or thermosetting adhesion, thereby enabling the throughput to be enhanced, including the process for manufacturing a product to which an actuator is applied, so that the cost of manufacturing can be reduced.

And, even if the actuator is activated by a higher field strength, the state of polarization remains unchanged, rather a more preferable state of polarization is provided, and therefore a higher degree of strain can be stably obtained. As a result, a compact actuator can be provided preferably.

In the cell driving type actuator 1, the degree of profile for the cell surface is preferably approximately 8 μm or less, and the amount of unevenness of the wall surfaces of the piezoelectric/electrostrictive elements, i.e., the driving parts forming a cell, is preferably approximately 10 μm or less. Moreover, the surface roughness Rt of the wall surfaces of the piezoelectric/electrostrictive elements, i.e., the driving parts forming a cell, is preferably approximately 10 μm or less. An actuator fulfilling at least one of these requirements has smooth inner walls of the driving parts forming a cell, thereby suppressing the concentration of the electric field and stress, and hence realizing a stable operation in the activation of respective cells.

The degree of surface profile is specified in Japanese Industrial Standard B0621 : “the definition and representation of geometrical deviation”. The surface profile implies a surface having a functionally predetermined shape, and the degree of profile for the surface is specified by the deviation of the surface contour from the geometrical contour, which is determined by theoretically predetermined dimensions. The cell surfaces in the present invention imply the inner wall surfaces of the driving parts forming a cell.

In the cell driving type actuator 1 shown in FIG. 1, the ratio of the minimum spacing between the adjacent piezoelectric/electrostrictive elements for forming a cell, i.e., the cell width W to the minimum spacing between the base plate and the cover plate, i.e., the cell height H, in other words, the aspect ratio W:H of a cell, is preferably substantially 1:2 to 1:40. The minimum spacing between the adjacent piezoelectric/electrostrictive elements for forming a cell, i.e., the cell width W, is preferably approximately 60 μm or less. More preferably, the aspect ratio W:H of a cell is 1:10 to 1:25 and the cell width W is approximately 50 μm or less. An actuator fulfilling at least one of these requirements, or, more preferably an actuator fulfilling both requirements, i.e., a thin actuator having a larger height provides a higher power with ease, thereby enabling a higher density to be realized, and making it possible to provide a more compact actuator.

Further, in the cell driving type actuator 1 shown in FIG. 1, the ratio of the spacing between a cell and the adjacent cell to the minimum spacing between the base plate and the cover plate is preferably approximately 1:2 to 1:40. The spacing between a cell and the adjacent cell, i.e., the cell spacing L, is preferably approximately 50 μm or less. More preferably, the ratio of the spacing between a cell and the adjacent cell to the minimum spacing between the base plate and cover plate is substantially 1:10 to 1:25, and the cell spacing L is approximately 30 μm or less. In the actuator fulfilling at least one of these requirements, or more preferably in the actuator fulfilling both requirements, each cell is independent of the cells adjacent thereto; nevertheless a greater number of cells can be provided, thereby providing a compact actuator.

When, therefore, the cell driving type actuator 1 according to the invention as shown in FIG. 1 is used as a liquid discharging device 100, a liquid can be simultaneously discharged from three adjacent cells 3, and the liquid can also be discharged with a higher density to an article to be sprayed.

Referring to the drawings which demonstrate the following application examples, the cell driving type actuator according to the present invention will be described hereinafter.

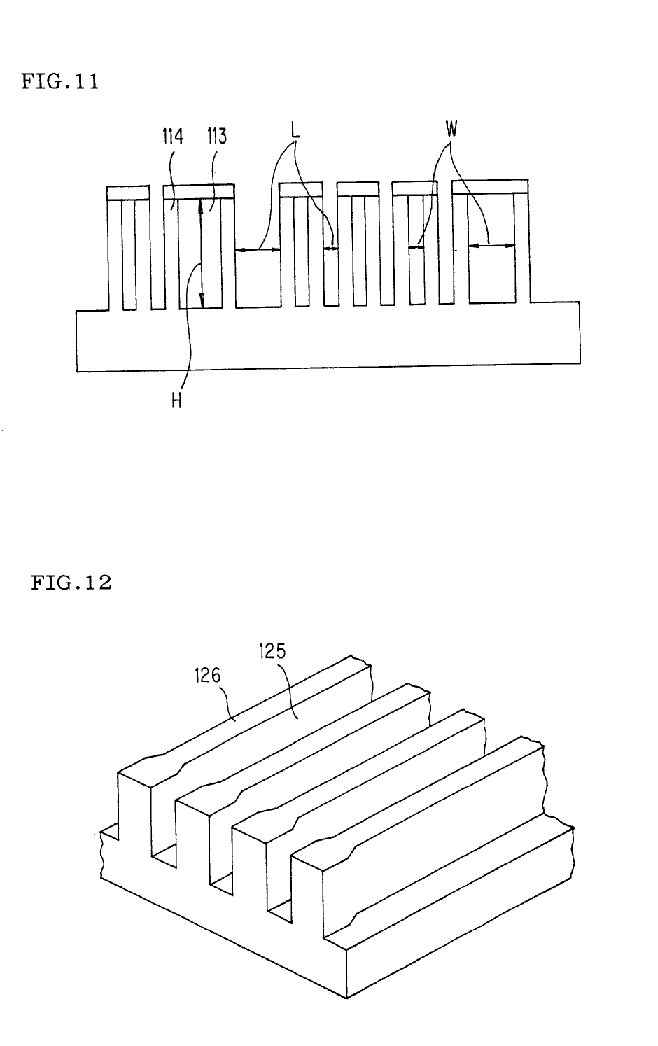

FIG. 11 is a sectional view of another embodiment of a liquid-discharging device, in which the cell driving type actuator according to the invention is used. In this case, the spacing between adjacent piezoelectric/electrostrictive elements forming a cell, i.e., the cell width W, and the spacing between a cell and the adjacent cell, i.e., the cell spacing L, have not been kept at fixed values, but have at least two different values. With this arrangement, it is possible to easily discharge a desired amount of the droplets onto a desired position of an object.

Moreover, FIG. 12 is a sectional view of another embodiment of a liquid-discharging device in which the cell driving type actuator according to the invention is used (the cover plate is not shown). The width of each comb-like piezoelectric/electrostrictive element, i.e., the width of each comb tooth 126, is determined in such a way that the width expands from the recess to the front end of the comb tooth. On the contrary, slits 125 forming a cell are constructed in such a way that they are narrower at the front end of the comb teeth 126. Such a procedure of increasing the width at the front end of the comb teeth provides a smaller stress due to the piezoelectric deformation of the junction to the nozzle plates (shown in FIG. 1, but not shown in FIG. 12) adhered to the comb teeth at the front end, thereby making it possible to increase the service life without interposing any other elements therebetween. A similar effect can be obtained if the comb teeth are masked from the front end up to a predetermined distance, thus maintaining an area where there is no electrode.

As shown in the embodiment in FIG. 12, by altering the width of the comb tooth from the recess to the front end of the comb tooth, optimal properties can be obtained for the cell driving type actuator according to the invention, wherein an optimal width of the slit is adjusted in accordance with the application. As another embodiment, a better shape of liquid channel can be formed in the application of a liquid discharging device.

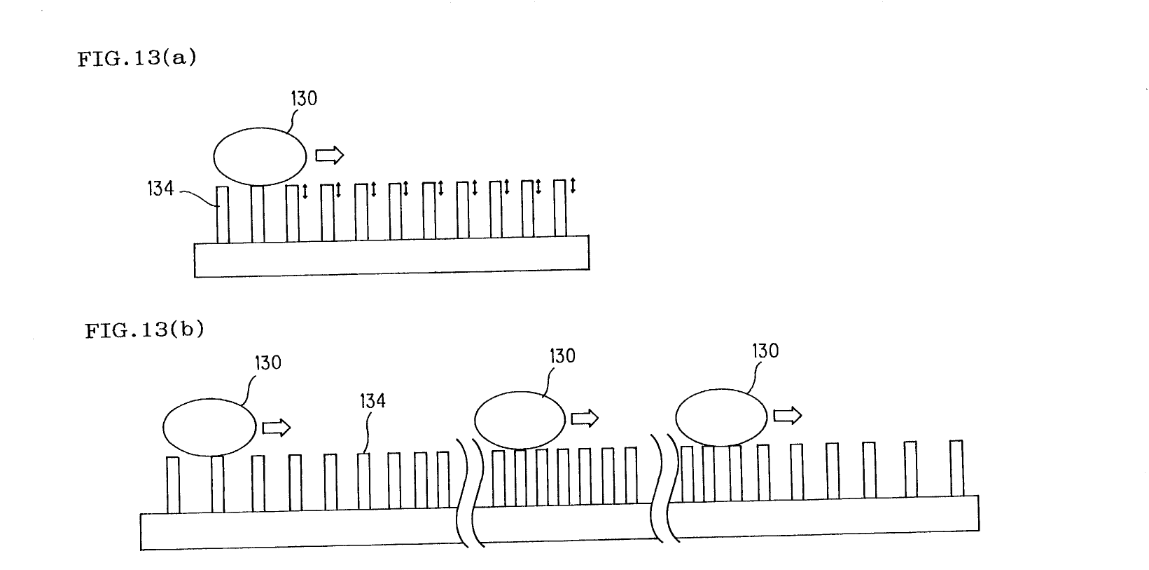

FIG. 13(a) and FIG. 13(b) show a transportation apparatus, in which the cell driving type actuator according to the present invention is used (although the cover plates are not shown, the cover plates can be removed). In FIG. 13(a), driving parts 134, that is, comb teeth, are constructed in such a way that the slits have the same width, thus providing transportation at a constant speed; whereas in FIG. 13(b), the driving parts 134, i.e., the comb teeth, are constructed in such a way that the width of a slit varies from position to position, hence the speed of transportation changes. An electric field is applied to the individual driving parts 134, as shown in FIG. 13(a), and then the driving parts 134 are deformed, thereby expanding or contracting in the direction indicated by the arrow, so that all the driving parts exhibit a wave-like displacement. Consequently, it is possible to convey a product 130 to be transported by carrying it on the wave. In the process of manufacturing fine products, there are several problems regarding the transportation thereof. However, if a transportation apparatus is formed by such a cell driving type actuator, it is possible to attain smooth movement in the transportation of micro-machines with ease.

Moreover, the cell driving type actuator according to the present invention can be used as an actuator for changing the direction of a light reflecting mirror; acting as, e.g., an optical switch for switching waveguides for optical signals in an optical communication network, or a projector component, or for a micro-mirror or the like used in a laser unit used in a CD-R/RW apparatus.

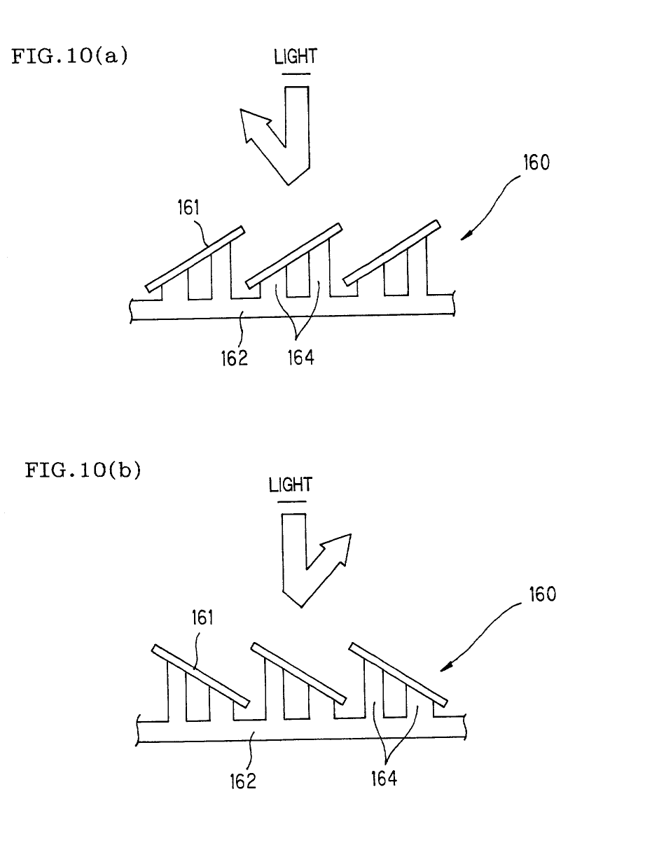

FIG. 10(a) and FIG. 10(b) are sectional views of a micro-mirror device in which the cell driving type actuator according to the invention is used. In this case, the direction of the surface of a mirror 161 is altered to reflect light in different directions. In a micro-mirror device 160, a plurality of driving parts 164 consisting of piezoelectric/electrostrictive elements are placed on a base plate 162 and a micro-mirror 161 is mounted onto, for instance, two to four driving parts 164. The expansion and contraction of specified driving parts 164, to each of which an electric field is applied, causes to change the direction of the micro-mirror 161 to change, thereby changing the direction of the reflected light.

Next, the method for manufacturing the cell driving type actuator according to the present invention will be explained. There are two manufacturing methods:

An example of the steps in the first method for manufacturing the cell driving type actuator is schematically shown in FIG. 4(a)-FIG. 4(e). In this manufacturing method a punch and a die are used: In FIG. 4(a), a predetermined number of green sheets 16 made of piezoelectric/electrostrictive material are diecut in a comb-like form with a punch, thus machining slit apertures 15 in each green sheet 16. In FIG. 4(b), the green sheets are positioned and laminated on a base plate 2, thereby forming the comb-like piezoelectric/electrostrictive elements having a predetermined thickness. Thereafter, the green sheets are fired and unified into one body, for instance, as shown in FIG. 4(c), and undergo the treatment for causing polarization, as shown in FIG. 4(d), and then electrodes 19 and the others are formed, as shown in FIG. 4(e). The method of positioning the green sheets in the lamination process is realized either by successively stacking said green sheets within a frame having the same inner shape which substantially corresponds to the outer shape of the green sheets, or by successively stacking said green sheets, for instance, by passing a guide pin through a predetermined guide hole in each green sheet, so that the positioning is carried out, for instance, under a pressurized state at a high temperature. In this case, the cover plate can also be formed by a green sheet of the same material, thereby the process of laminating, firing and unifying into one body is similarly applied.

Subsequently, the second manufacturing method will be explained based on the drawings:

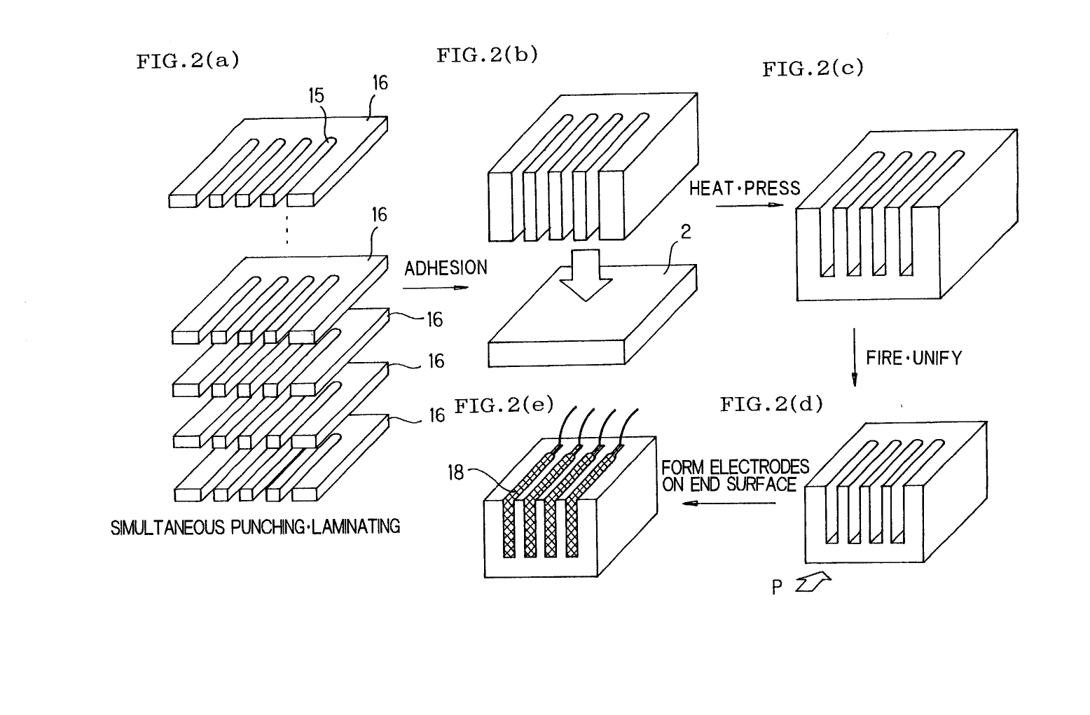

FIG. 2(a)-FIG. 2(e) are drawings showing an embodiment of the second method for manufacturing the cell driving type actuator according to the invention. FIG. 2(a)-FIG. 2(d) schematically show the steps of the process, and FIG. 2(e) schematically shows a finished actuator.

The second manufacturing method comprises the steps of: firstly forming slit apertures 15 in a green sheet 16 (hereafter simply denoted by sheet), as in FIG. 2(a), and at the same time, laminating with a method which will be described later; forming comb teeth by laminating the sheets 16; and then completing the lamination just after punching, thereby forming comb-like piezoelectric/electrostrictive elements having a predetermined thickness. Subsequently, for instance, comb teeth are formed on the base plate 2 made of the sheets prepared for independently, and the sheets laminated are laid on the base plate in FIG. 2(b). In FIG. 2(c), all of the sheets are pressurized under heating, thus bringing them into tight contact with each other. In FIG. 2(d), all the sheets and the base plate 2 are unified by firing, thereby finishing the driving parts. After that, electrodes 6 are formed on the wall surfaces of the slits, thus enabling the finished cell driving type actuator to be provided as in FIG. 2(e). The green sheets can be formed by conventional means for forming a film, such as the doctor blade method.

In the second method for manufacturing the cell driving type actuator according to the present invention, the slit wall surfaces, which will later become a cell, are formed by fired surfaces, and therefore micro cracks and fractures inside grains, both appearing in the case of machining slits with a dicing unit or the like, do not occur, so that no deterioration in the characteristics occurs, thereby enhancing the durability and reliability. Moreover, fractures at the corners (chipping) hardly occurs during machining, and there is no need for the steps of cleaning and drying, because no dicing step is employed.

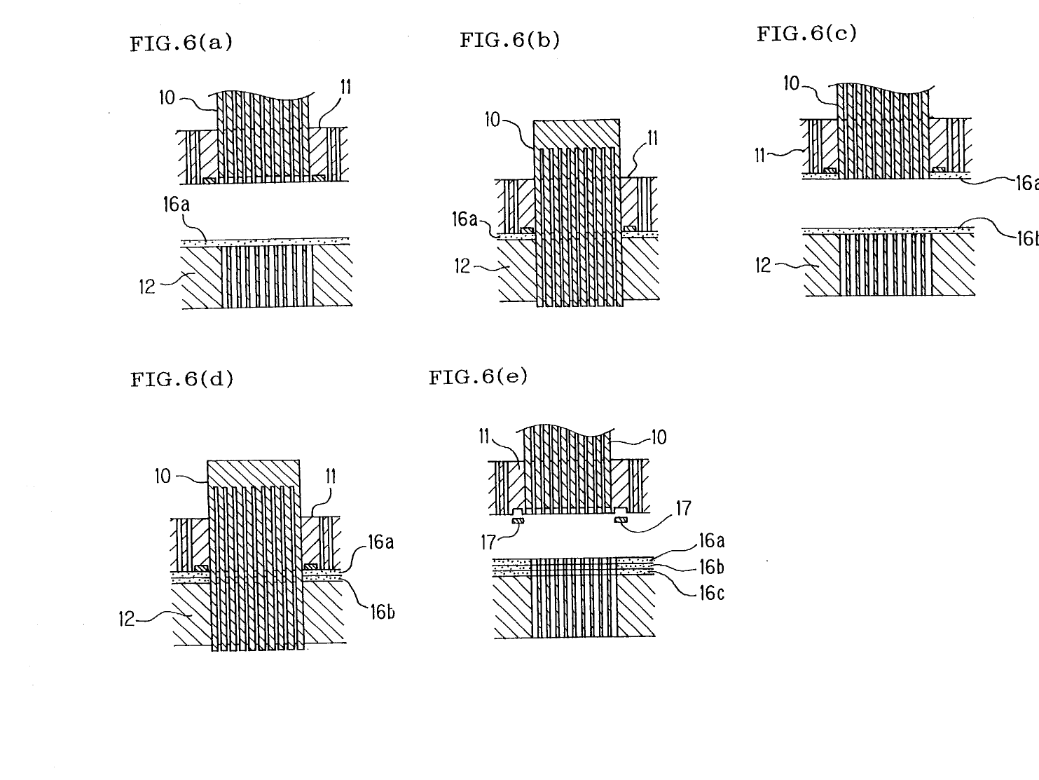

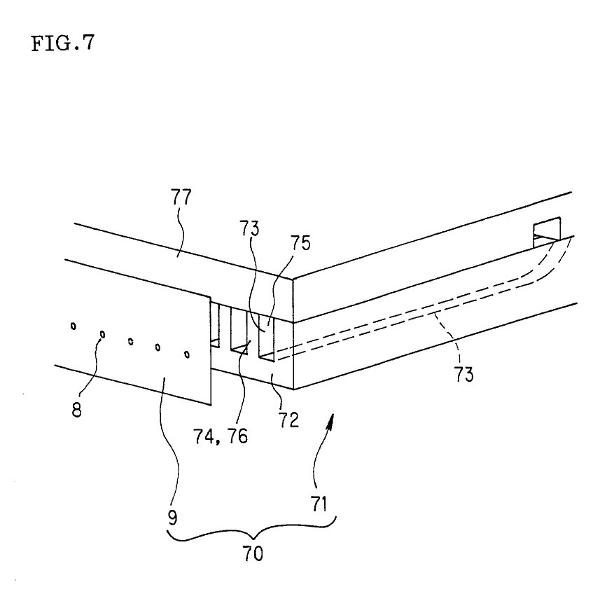

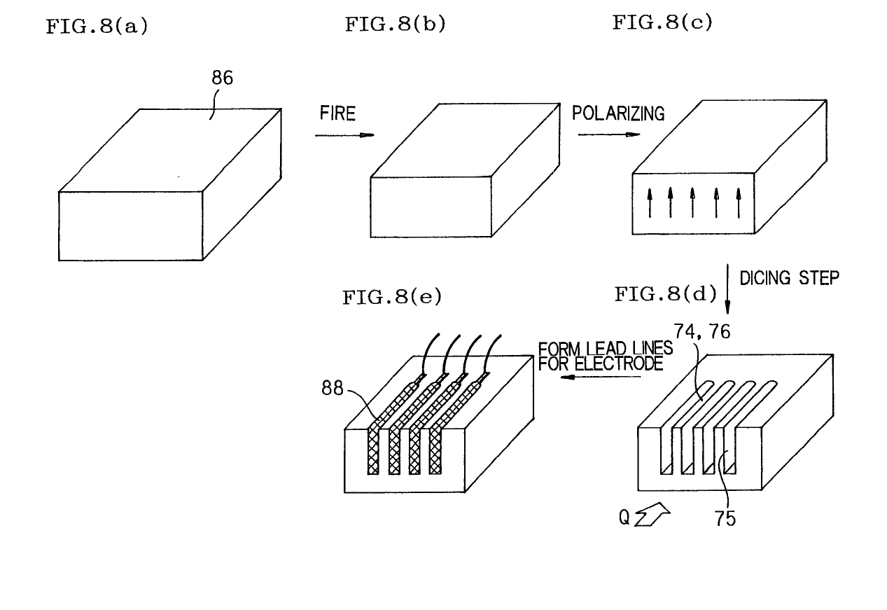

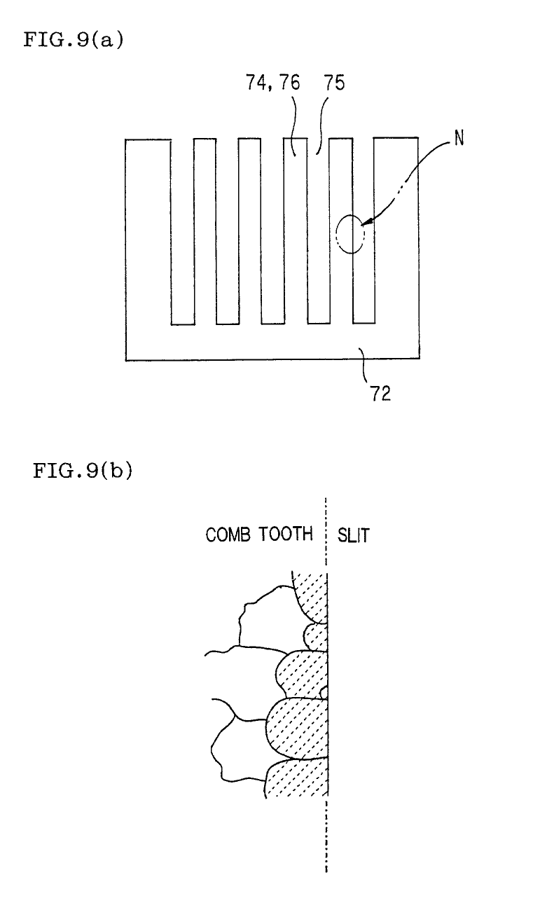

FIG. 6(a)-FIG. 6(e) show the concrete steps of simultaneous punching and laminating method employed in the above-mentioned second method. In this case, a die assembly consisting of a punch 10 and a die 12 is used, and a stripper 11 for laminating the sheets 16 is arranged around the die assembly. FIG. 6(a) shows a first sheet 16a laid on the die 12 before punching. In FIG. 6(b), the punch 10 and stripper 11 fall, thus punching slit apertures punched in the sheet 16, and then comb teeth are formed (first step).

Then, a second sheet 16b is provided for punching. In this case, as shown in FIG. 6(c), the first sheet 16a is moved upwards into tight contact with the stripper 11 and is then removed from the die 12 (second step). The method for tightly covering the sheet 16 on the stripper 11 can be realized, for instance, by evacuating suction openings formed in the stripper 11.

In order to diecut the second sheet 16b, the punch 10 and the stripper 11 are moved upwards from the die 12, too. In the upward movement, preferably, the front end of the punch 10 should not be inserted into the slit apertures of the first sheet 16a which simultaneously moves upwards, and in the case of deactivation, it is important to fix the front end at a position slightly withdrawn from the lowest part of the first sheet 16a which simultaneously moves upwards (third step). If the punch 10 is returned to the slit apertures of the first sheet 16a, or is completely inserted into the stripper 11, the slit apertures formed are deformed, because the sheet 16a is soft. Therefore, the flatness of the side surface of the comb teeth is reduced when the sheets 16 are laminated to form the comb teeth.

FIG. 6(d) shows the step of punching the second sheet 16b. The second sheet 16b can easily be laid on the die 12 by tightly stacking the first sheet 16a on the stripper 11, so that punching can be performed as in the process of FIG. 6(b), and at the same time, the second sheet is laid on the first sheet 16a (fourth step).

By repeating the steps of FIG. 6(c) and FIG. 6(d), the second sheet 16b is laid on the first sheet 16a, these sheets are moved upwards (fifth step), and then the third sheet 16c is prepared for punching. In this case, it is also important to keep the sheet at a position slightly withdrawn from the under part of the sheet 16 which simultaneously moves upwards (sixth step). After that, by repeating the fourth step to the sixth step, the punching and laminating are repeated till a necessary number of the sheets 16 are obtained.

FIG. 6(e) shows the state in which the punching has been completed. After the punching and laminating of the necessary number of the sheets 16 are completed, the sheets 16 which are held by the stripper 11 are released, and the punched and laminated sheets 16 can be taken out after removing them from the stripper 16. The removing from the stripper 11 can be securely achieved by applying a separation tool 17 to the under surface of the stripper 11. The above-mentioned procedure is that used in the manufacturing method disclosed in Japanese Patent Application No. 2000-280573, and a comb-like multi-slit laminated product having a predetermined thickness can be obtained with this procedure.

Thereafter, for instance, the laminated product is laid on the base plate 2 comprising green sheets of the piezoelectric/electrostrictive material, and the lamination step is performed under pressure, thereby producing a handy lamination product. Subsequently, the laminated product is fired and unified under conditions suitable for the properties of the sheet, thereby enabling the cell driving type actuator to be obtained.

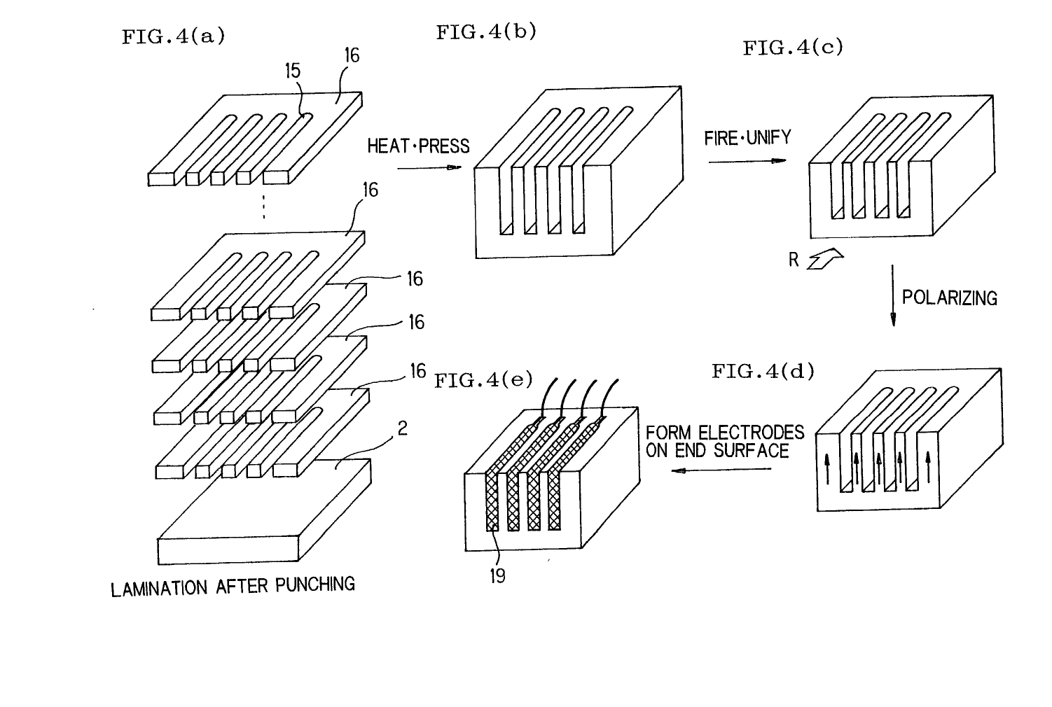

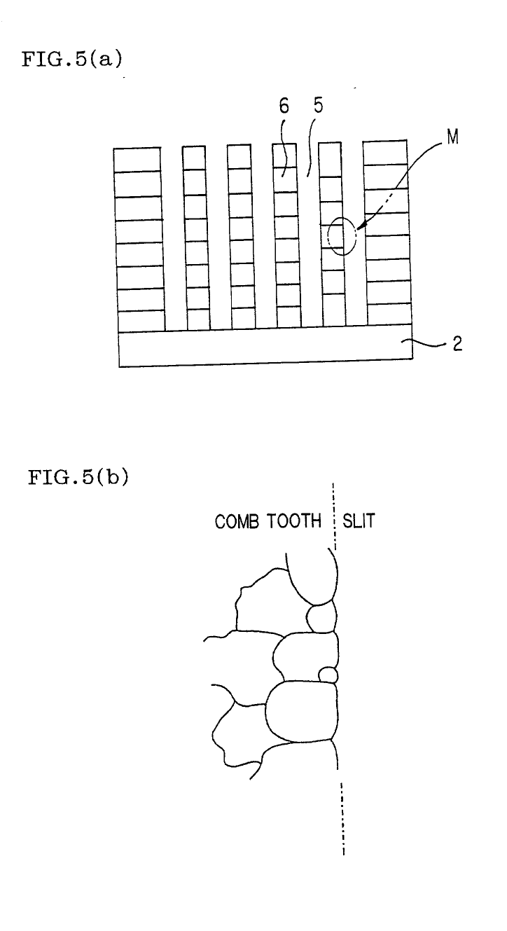

FIG. 5(a) shows a side surface viewed from P in FIG. 2(d), and FIG. 5(b) schematically shows an enlarged section of part M in the wall surface of slit 5 shown in FIG. 5(a). The accuracy in stacking the green sheets in the second method for manufacturing the cell driving type actuator according to the present invention is described in an exempla: in the case where 10 green sheets each having a thickness of 50 μm and a Young's modulus of 39 N/mm² are punched to form teeth of a comb to provide a slit width of 50 μm and a comb tooth width of 30 μm, and then laminated, the deviation between the respective layers after firing is 4 μm at maximum and the surface roughness Rt is approximately 7 μm. As shown, comb teeth having smooth and uneven side surfaces can be provided. Moreover, the slit width after firing was about 40 μm due to contraction during firing.

As in the above, forming slit apertures in the green sheets with the die and punch simultaneously allows the green sheets to be laminated. The punch itself can be used as an axis for adjusting the laminating position of the green sheets, and the deformation of the apertures in the punched slits can be avoided with the aid of the punch. As a result, no deformation occurs in the slit apertures and the deviation between laminated green sheets is reduced to be 5 μm or less. Therefore, it is possible to obtain high precision lamination and to form uneven wall surfaces of the slits. Hence, slits having a high aspect ratio of 10 to 25, said slits later forming the cells, can be formed with ease, even for comb tooth having a slit width of less than 70 μm, and an actuator having excellent properties can be provided.

Since, moreover, there are neither micro cracks in the wall surfaces of slits between comb teeth nor fractured particles inside grains, no deterioration of the characteristics due to residual stress occurs. The above-mentioned second method requires neither tools for moving the sheets nor spaces for stacking the sheets, thereby simplifying the production line and enabling low cost production to be obtained.

In the above-mentioned first and second manufacturing methods, moreover, the slit width is substantially the same as the punch machining width in the die assembly when the sheets are punched. However, since the sheets contract during firing, the combination of thin machined slits and the shrinkage during firing makes it possible to form very small slits having a thickness of 40 μm or less. In accordance with the design of the die assembly for punching, e.g., changing the shape of the die, slits having a shape other than a straight line can easily be formed, so that an optimal shape can be provided in accordance with the application.

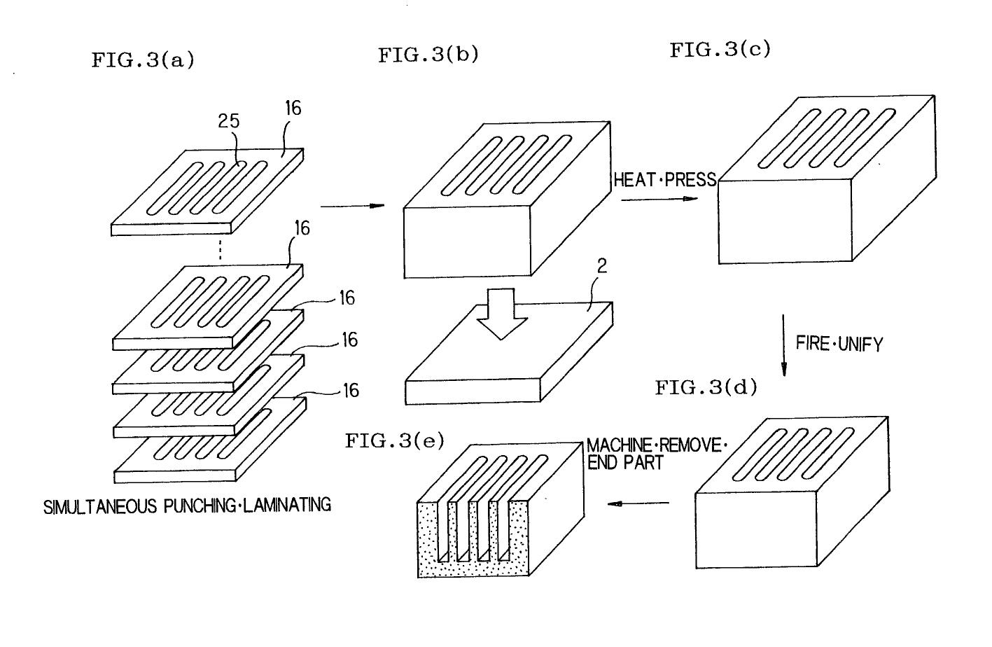

FIGS. 3(a)-FIG. 3(e) show another embodiment of the second method for manufacturing the cell driving type actuator according to the present invention.

Firstly, as in FIG. 3(a), both forming of slit apertures 25 and laminating are simultaneously carried out on each sheet 16, thereby providing a laminated product. After completing the forming of the apertures and lamination, the laminated product is laid on the base plate 2 consisting of green sheets 16 in FIG. 3(b), and then, for instance, all of the layers are pressurized under heating, thereby being brought into tight contact with each other, as shown in FIG. 3(c), and they are fired and unified into one body as shown in FIG. 3(d). These manufacturing steps are identical to those in FIG. 2. In this example, however, the slit apertures punched are elongated, both ends thereof being closed, and are formed in a comb-like shape by cutting them at one end after firing, as shown in FIG. 3(e). Then, after forming electrodes and the like, the manufacturing process is completed.

In such a method of lamination without direct punching of comb teeth, but connecting them to each other at both ends of the comb teeth, a process of cutting the end part is required after firing, hence steps of cleaning and drying the parts after removing them are required. Nevertheless, the accuracy of stacking comb teeth in the sheets can be further enhanced.

As above-mentioned in detail, the present invention solves the first to eighth problems in the conventional art, and offers a cell driving type actuator and a method for manufacturing the actuator, wherein a heating process at a high temperature can be applied; mass production at low cost is possible; the slit portions each have a cell which has a shape other than a straight one, a width of 60 μm or less, and a high aspect ratio; the cells can be activated with a higher electric field strength; and the actuator is based on the principle of the piezoelectric/electrostrictive effect where a greater displacement can be obtained with a smaller electric field strength.

What is claimed is:

1. A cell driving type actuator wherein a plurality of piezoelectric/electrostrictive elements are arranged in alignment like teeth of a comb on a base plate and said actuator is a piezoelectric/electrostrictive actuator being driven by means of dislocation of piezoelectric/electrostrictive elements,
characterized in that each of cells is formed independently from its adjacent cells by closing respective planes being positioned between two adjacent piezoelectric/electrostrictive elements and facing the base plate with respective cover plates.

2. A cell driving type actuator according to claim 1, wherein the polarization field of said piezoelectric/electrostrictive elements and the driving electric field are aligned in the same direction.

3. A cell driving type actuator according to claim 1, wherein the degree of profile for the surface of said cell is approximately 8 μm or less.

4. A cell driving type actuator according to claim 1, wherein the ratio of the minimum spacing between the adjacent piezoelectric/electrostrictive elements forming said cell to the minimum spacing between said base plate and said cover plate is approximately 1:2 to 1:40.

5. A cell driving type actuator according to claim 1, wherein the ratio of the spacing between said cell and the adjacent cell to the minimum spacing between said base plate and said cover plate is approximately 1:2 to 1:40.

6. A cell driving type actuator according to claim 1, wherein the minimum spacing between the adjacent piezoelectric/electrostrictive elements forming said cell is approximately 60 μm or less.

7. A cell driving type actuator according to claim 1, wherein the spacing between said cell and the adjacent cell is approximately 50 μm or less.

8. A cell driving type actuator according to claim 1, wherein the surface roughness Rt of the wall surfaces of the piezoelectric/electrostrictive elements is approximately 10 μm or less, said elements facing one another and forming said cell.

9. A cell driving type actuator according to claim 1, wherein the width of the comb-like piezoelectric/electrostrictive elements varies from a recess to the front end of the comb tooth.

10. A cell driving type actuator according to claim 1, wherein the spacing between the adjacent piezoelectric/electrostrictive elements forming said cell, or the spacing between said cell and the adjacent cell has at least two different values.

11. A liquid discharging device equipped with the cell driving type actuator according to claim 1, wherein, each cell is used as a liquid pressurizing chamber, and said piezoelectric/electrostrictive elements are displaced by applying a driving electric field thereto in the same direction as the polarization field of said piezoelectric/electrostrictive elements, thus deforming said liquid chamber, thereby enabling a liquid filled in said liquid chamber to be discharged in the direction of the front end of the comb teeth.

12. A method for manufacturing, by utilizing a punch and a die, a cell driving type actuator wherein a plurality of piezoelectric/electrostrictive elements are arranged in alignment like teeth of a comb on a base plate; each cell being formed by closing two adjacent piezoelectric/electrostrictive elements disposed on the base plate with a cover plate positioned at a plane facing the base plate in such a manner that said cell is formed independently from its adjacent cells,
characterized in that said method comprises the steps of:
providing a plurality of green sheets made of piezoelectric/electrostrictive material,
machining slit apertures in all of said green sheets with said punch, laminating all the green sheets after positioning them, thus forming comb-like piezoelectric/electrostrictive elements.

13. A method for manufacturing, by utilizing a punch and a die, a cell driving type actuator wherein a plurality of piezoelectric/electrostrictive elements are arranged in alignment like teeth of a comb on a base plate; each cell being formed by closing two adjacent piezoelectric/electrostrictive elements disposed on the base plate with a cover plate positioned at a plane facing the base plate in such a manner that said cell is formed independently from its adjacent cells,
characterized in that said method comprises:
a step of providing a plurality of green sheets made of piezoelectric/electrostrictive material,
a first step of machining first slit apertures in a first green sheet with the punch,
a second step of moving the first green sheet upwards into tight contact with a stripper in the state of not withdrawing the punch from the first slit apertures,
a third step of moving the punch upwards in such a way that the front end of the punch is withdrawn slightly from the lowest part of the first green sheet which moves upwards,
a fourth step of machining second slit apertures in a second green sheet with the punch,
a fifth step of moving the second green sheet upwards, together with the first green sheet in the state of not withdrawing the punch from the second slit apertures,
and a sixth step of moving the punch upwards in such a way that the front end of the punch is withdrawn slightly from the lowest part of the second green sheet which moves upwards, and thereafter,
laminating a plurality of green sheets by repeating the fourth to sixth steps so as to form a plurality of comb-like piezoelectric/electrostrictive layers.
